(19) United States
(12) Patent Application Publication
(10) Pub. No.: US 2026/0044071 A1
(43) Pub. Date: Feb. 12, 2026

(54) Stamp and Method for Imprinting

(71) Applicant: Morphotonics Holding B.V., Veldhoven (NL)

(72) Inventors: Marc Dielen, Veldhoven (NL); Nico Jansen, Veldhoven (NL); Jan Matthijs Ter Meulen, Veldhoven (NL)

(21) Appl. No.: 19/102,457

(22) PCT Filed: Aug. 10, 2023
(86) PCT No.: PCT/NL2023/050422

§ 371 Date: Feb. 10, 2025

(30) Foreign Application Priority Data
Aug. 11, 2022 (EP) 22189885.1

(51) Int. Cl. G03F 7/00

(52) U.S. Cl. CPC G03F 7/0002

(57) ABSTRACT

A stamp for imprinting and a corresponding method for producing an imprinted substrate having a variable depth pattern, in particular by using a stamp according to the present invention. The invention enables the provision an imprinted product having a variable depth pattern due to the invention making use of a stamp including at least one textured area at least one barrier adjacent to at least part of the textured area.

### CROSS-REFERENCE TO RELATED APPLICATIONS

This application is the United States national phase of International Patent Application No. PCT/NL2023/050422, filed Aug. 10, 2023, and claims priority to European Patent Application No. 22189885.1, filed Aug. 11, 2022, the disclosures of which are hereby incorporated by reference in their entireties.

### BACKGROUND OF THE INVENTION

### Field of the Invention

The invention relates to a stamp for imprinting, in particular nanoimprinting. The invention further relates to a method for imprinting, and in particular for producing an imprinted substrate having a variable depth pattern. The invention also relates to an imprinted product.

### Description of Related Art

Textures on the micro-and nanometer scale have gained significantly in interest and importance during the past decades. Especially for optical applications e.g. in displays or photovoltaic cells, textures with an optical effect which e.g. comprise micro or nano-lenses, play an important role to enhance the performance.

Typically, textures with optical effect are formed by covering a substrate such as a display panel or a panel of glass with a lacquer or a resin, texturing the lacquer using a mold or a stamp, consolidating the lacquer or resin using e.g. heat, radiation or any other conditions while the resin or lacquer is in contact with the stamp or mold and remove the stamp or mold from the consolidated resin layer. Processes which provide surfaces with a texture are typically called texturing processes or imprinting processes and both expressions are used synonymously herein. Depending on the size and the properties of the substrate and the stamp, typically roll-to-roll processes, roll-to-plate processes and plate-to-plate processes are distinguished. In roll-to-roll processes a long web-like substrate such as a foil, a fabric or thin-sheeted metal is treated by a textured roller or by a stamp which is pressed against the web-like substrate by a roller. Typically, roll-to-roll processes are carried out continuously. In plate-to-plate processes, rigid, discrete substrates are textured by discrete stamps mounted on a rigid chuck. Typical substrates to be textured in plate-to-plate processes are semiconductor wafers of e.g. silicon. For this reason, plate-to-plate processes are also called “wafer-scale processes”. The size of both substrates and stamps is very limited in plate-to-plate processes and plate-to-plate processes are by construction discontinuous. In roll-to-plate processes, a rigid plate-like substrate is textured by either a textured roller or by a stamp which may be a flexible stamp or a rigid stamp pressed against the substrate using a roller. Like in plate-to-plate processes, discontinuous or discrete and rigid substrates can be textured using roll-to-plate processes, however the size limits of plate-to-plate processes do not apply. Thus roll-to-plate processes enable the texturing of large, rigid panels of material such as plates for photovoltaic modules, smart windows, displays or other products. A typical feature of roll-to-plate as well as of roll-to-roll processes in contrast to plate-to-plate processes is that pressure is not exerted uniformly to the whole surface which is textured but in a moving manner in which a line pressure follows the movement of the imprinting roller. Due to the movement of the flexible stamp, which is typically used in roll-to-plate imprinting processes, or of the roller relatively to the substrate, surplus lacquer or resin could be forwarded opposite to the imprint direction or pressed aside or even backwards. How much of the surplus lacquer is being forwarded and possibly could overflow the designated imprinting area depends, among other things, on several characteristics, such as for example substrate-to-substrate surface height variation, caused e.g. by irregularities in the substrate or thickness variations; resin layer thickness variation, by either variation in the coating process or rheological property variation of the lacquer itself; defects and/or height variations in the flexible stamp or mold; and/or pressure (imprinting force) of the roller. With near zero pressure (force) the surplus of lacquer will not be pushed forward, however the texture replication will not be sufficient either, since the textures will not be filled completely by the lacquer. If not enough lacquer is used this only gives partial imprinting at the end, i.e. either the texture will not be fully replicated, or parts of the substrate will not have a texture at all. When a surplus of lacquer is used this can cause an overflow of lacquer at the beginning, the sides and at the end of the imprint area. Therefore, the sides of the panels might lose functionality or will look visually less appealing. Furthermore, the overflow area will require additional space on the substrate. Control of resin overflow is thus of utmost importance in roll-to-plate processes.

A non-limiting practical example of a functional texture is the imprinting of lenses to a product which may e.g. improve the visual experience. Images can be rendered sharper or even become visible with 3D effect. But sometimes these options have to be switchable. At certain moments it may be preferred to look with a standard view, in other situations the vision is preferred with the adjusted optics. In other words, the optical effect has to be switchable. The switchable effect can be obtained with a transparent conductive layer, for instance an indium-tin oxide (ITO) layer, an optical layer and a liquid crystal with switchable refractive index. In this design the imprinted layer with optical texture is placed in between the conductive layer and the liquid crystal. Adjacent to or surrounding said transparent conductive layer, a contact area may be located which is of an electrically conductive material that is not necessarily transparent. The whole assembly of the transparent conductive layer and the electrically conductive material may be in part or in total be surrounded by a sealing area which may e.g. be of a non-conductive material. The sealing area may be covered by a seal. This seal can be an adhesive material as for example an UV curable epoxy resin. Preferably this seal has a low permeability for air- and/or water such as adhesives containing water absorbers, which could also be referred to as scavengers or getters. This design has practical challenges. The transparent conductive layer has to make contact with the power source. The imprint layer will cover the electrically conductive material at the contact areas, limiting the contact. Further, the imprint layer is relatively thick. Cured acrylate-based resins are typically permeable for water on a longer time scale. This way, a thick acrylate layer on seal may serve as a permanent entry for reasonable amounts of moisture limiting the lifetime of the device. A resin layer in between the seal and a possible top seal should thus be as thin as possible in order to minimize the transition pathway for moisture. Moreover, if the seal is placed on a textured surface, the seal adds to the total thickness of the device. Hereby the total device thickness will be thicker. Additionally, the dosing and thickness control of a seal placed on a texture with varying heights is complex. Standard solutions for this problem are the removal of the texture at the contact and seal position, lowering the impact of the thickness at the seal and thus in fact creating a thinner display, making it flat and removing any potential water leakage paths. This could be done amongst others mechanically, by ablation, using solvents or by etching. But this additional step is costly and will likely pollute the device as either particles, fumes or etching chemicals may soil the functional region of the device.

### SUMMARY OF THE INVENTION

It is thus an object of the present invention to provide a solution for the abovementioned drawbacks or least provide an alternative for the production of functional textured layers or devices.

The invention provides thereto a stamp for imprinting, in particular nanoimprinting, comprising:
at least one textured area; and
at least one barrier adjacent to at least part of the at least one textured area;
   wherein at least one barrier in particular extends over at least the length of at least one side of the textured area, and in particular wherein at least part of at least one barrier has a substantially uniform height which is higher than the highest peak of the at least one textured area.

The stamp according to the present invention is in particular suitable for texturing a resin layer on a substrate. The stamp according to the present invention enables the production of a textured product or substrate, having a textured area which is at least partially adjacent and/or surrounded by at least one contact surface, wherein the maximum residual layer thickness of at least one contact surface is smaller than the maximum residual layer thickness of the imprinted textured area. At least part of at least one barrier having a substantially uniform height which is higher than the highest peak of the at least one textured area enables that during imprinting the barrier can form a substantially uniform area having a relatively thin thickness can be created which can function as a contact surface. Such contact surface(s) could for example be used for enabling electrical and/or thermal contact, providing electronic elements and/or for sealing purposes. Due to the effective configuration of the stamp, the use of additional processing steps, such as etching, mechanical removal or ablation to form a contact surface can be omitted. In particular, the use of the barrier according to the present invention contributes to achieving this result. The present invention, in particular the stamp and/or the method according to the present invention, enable the production of an imprinted product having a substantially uniform area having a thickness of 5 μm or less. Such area can thus function as contact surface.

The stamp according to the present invention is in particular configured for use in a method according to the present invention. The textured area of the stamp typically comprises depressions and elevations. Said depressions and elevations can be configured for creating a volume to obtain at least a fraction of resin or lacquer. The stamp can for example be a substantially flexible stamp. However, it is also conceivable that the stamp is a substantially rigid stamp and/or that the stamp is a formed by a roller, in particular a textured roller. Possibly, a stamp according to the application comprises a textured layer comprising openings and elevations which form a texture on the first side of the textured layer while the second side of the textured layer may be fixed to a carrier such as a handle robot arm, a roller, a metal or glass sheets or a carrier foil. In case a carrier foil is used, the whole stamp including the carrier is an essentially two-dimensional sheet-like structure. Stamps of this shape can be called “flexible stamps” or, short, “flex stamps” throughout this application. In flexible stamps, the carrier may also comprise several layers. At least one of said layers should be a resin layer, however the carrier may also comprise reinforcement materials such as thin, bendable glass sheets. In an embodiment, the textured layer of the stamp is not fixed to any carrier but the stamp consists only of the textured layer. Also in this case, the stamp may be flexible. The textured layer of the stamp may be of any material known to the person skilled in the art such as metal, quartz, silicon, glass or polymers like acrylate resins, epoxy resins or elastomeric resins such as rubber. The stamp according to the application may e.g. transfer ink, resin or lacquer onto a surface and thus produce an imprinting pattern on an external surface similar to the working principle of an office stamp. In this mode of operation, the elevations of the textured layer or textured area of the stamp are wetted with ink, lacquer or resin and then pressed on the target surface in such a manner that on the target surface, the parts of the stamp that have been wetted with ink or resin become visible. Said principle is known as relief imprinting. The stamp may also be brought in contact with a liquid, molten or viscous material either on the stamp itself or on a surface in such a way that said liquid, molten or viscous material adapts to the texture of the stamp and is hardened e.g. by heating, cooling or by electromagnetic radiation while being in contact with the stamp. Upon removal of the stamp, the negative image of the stamp is then formed in the hardened material which is thus textured like a spot of molten wax on a document by a traditional seal matrix. This imprinting principle is known as intaglio imprinting.

The depressions and elevations of the stamp may thus, depending on the imprinting principle, either form a positive or a negative image of the texture which is produced by the stamp depending on whether the principles of relief or intaglio imprinting are used. The height of the elevations as well as the depth of the depressions is not particularly limited, however, neither the height of the elevations nor the depth of the depressions should adversely affect the handleability and the mechanical stability of the stamp. Mechanical stability is of utmost importance if there is no carrier which stabilizes the textured layer of the stamp. In this case, the thickness of the textured layer has to be large enough for not forming predetermined breaking points in the textured layer, especially in cases where the textured layer is exposed to tension during the imprinting or texturing process. Handleability is of importance if the stamp is used as a flexible stamp. For flexible stamps, bending properties are important and the height of elevations compared to the rest of the textured layer of the stamp must not adversely affect the flexibility of the stamp. Depending on the imprinting technique to be used, different elevations may have different heights and/or different depressions may have different depth.

The stamp according to the present application could possibly comprise elevations in its blank area which by their height and/or size allow for the formation of a resin layer of a thickness of at most 5 microns. Such elevation or elevations could form a barrier within the context of the present invention. In the following, these elevations will be called “extended elevations”for the sake of brevity. The extended elevations are located in the blank area. The extended elevations may be located adjacent to the active area. In an embodiment, the extended elevations form kind of a frame around parts of the active area or around the whole active area. Hence, an embodiment is also conceivable wherein at least one barrier forms a frame around part of at least one textured area or said frame may enclose the textured area fully.

In a possible embodiment, at least one barrier substantially encloses the at least one textured area. At least one barrier may surround the textured area. The barrier is possibly positioned at a distance from the textured area, for example at a distance of at least 0.5 μm. Preferably, the height of the barrier is substantially uniform over the entire barrier. At least one barrier defines a width and a height, wherein the height of at least one barrier is substantially uniform and/or wherein the width of the barrier is substantially uniform. A substantially uniform barrier could positively contribute to the provision of a uniform and/or consistent contact surface in the product which is to be obtained. It is conceivable that at least one barrier has a substantially uniform width and/or height over the entire length of the barrier.

At least one barrier is preferably a continuous barrier. It is conceivable that at least one barrier is an uninterrupted barrier. Hence, in a possible embodiment, at least one barrier is a continuous barrier which fully encloses the textured area. The use of a continuous barrier can also positively contribute to achieving a consistent and well defined product as the barrier can prevent that undesired residues of resist will be present which could negative affect the product. A consistent contact surface will also result in a more consistent and reliable product.

In a preferred embodiment, at least one barrier comprises a substantially flat end surface. The use of a substantially flat end surface will result in a substantially flat and consistent contact surface obtained after imprinting using the stamp according to the present invention. It is for example imaginable that the end surface of at least one barrier is substantially level with the layer thickness or a base surface of the stamp. It is also imaginable that the end surface of at least one barrier is at least partially structured. It is for example possible that at least part of the end surface of at least one barrier is substantially structured such that a substantially roughened contact surface is provided. This could be beneficial for subsequent bonding steps applied to the obtained product. It is also imaginable that at least part of the contact surface is roughened. At least part of the contact surface can be applied as bonding surface.

It is also imaginable that the stamp comprises multiple barriers. It is for example imaginable that a plurality of barriers encloses the textured area. It is for example also imaginable that a repeated pattern is applied, wherein at least two textured areas and at least two barriers are present. It is also imaginable that at double barrier configuration is applied.

In a possible embodiment, the stamp comprises at least one reservoir element and preferably a plurality of reservoir elements, said reservoir element or reservoir elements defining a reservoir volume. At least one reservoir element can for example comprise at least one reservoir elevation, and preferably a plurality of reservoir elevations. At least one reservoir element is preferably positioned adjacent to at least one barrier. More in particular, at least one reservoir element is preferably positioned on an opposite side of at least one barrier with respect to the textured area. It is imaginable that the defined reservoir area is open to the edges of the stamp in such a way that excess of resin can flow out during imprinting. The reservoir elements are preferably configured to guide excess resin away from the textured area and the barrier(s). In a beneficial embodiment, at least one reservoir element is located at least one outer edge or at the circumference of the stamp. In this configuration, the reservoir element(s) will not affect the primary elements of the stamp. It is for example imaginable that at least one reservoir element is positioned adjacent to at least one barrier elements. It is also imaginable that at least one barrier element is substantially enclosed by a plurality of reservoir elements which in particular define a reservoir volume. It is imaginable that at least one reservoir element has a height which is equal to or smaller than the maximum height of at least one barrier. Preferably the height of at least one reservoir element is substantially equal to the maximum height of at least one barrier. The height of at least one reservoir element could also be smaller or bigger than the maximum height of at least one barrier. At least one reservoir element is for example defined by an elevation having a height which is equal to or smaller than the maximum height of at least one barrier. The elevations can for example allow for formation of a resin layer of a thickness of at most 5 micron on a substrate and the elevations can be interrupted by channels which allow resin to flow between the active area and the blank area of the product during the imprinting process.

The stamp according to the present invention can be configured to create a product having a blank area and an active area. The product can for example have a resin layer which resin layer has an active area and a blank area wherein the resin layer preferably has a thickness of at most 5 microns in at least 15% of the blank area. It can also be said that the stamp has a blank area and an active area. The active area can be defined by the textured area and/or at least one barrier. In an embodiment, the blank area of the stamp comprises domains of open volumes which are of same height or greater or lower than the height of the active area and which thus may gather resin outside the active area. The area of same or greater or lower height may be called reservoir area as it may take the resin overflow that may be produced in the active area. From the active area, the reservoir area may be separated by the extended elevations. In an embodiment, the reservoir area is not a singular depression with a large surface in the textured layer of the stamp but comprises small elevations. This is of importance if the stamp is a flexible stamp as especially in roll-to-plate imprinting, large depressions in flexible stamps may be squeezed by the pressure of the imprinting roller leading to uncontrolled resin flow with a lot of negative effects on both the imprint result and also the equipment. The imprint result may become faulty as resin may get to positions where it is unwanted and the equipment may be soiled by splashed resin. Especially for flexible stamps in roll-to-plate processes, it is thus important that depressions of large surface area are supported. The elevations which support the reservoir areas may be shaped like columns and thus support the reservoir area like a micron-or nano-scale columned hall. In an embodiment, the blank area of the stamp is shaped such that either at the whole circumference of the blank area or at certain positions resin may flow out in a controlled manner. This means that underneath the stamp, resin flow is not blocked but that, for the purpose of controlling the pressure and the resin amount underneath the stamp, the blank area may comprise outlets. In one embodiment, said outlets may be formed in such a way that the “columned hall structure” of the reservoir texture reaches out till the edges of the textured layer either on the whole circumference of the stamp or at certain positions only.

In an embodiment, the extended elevations do not form a solid border around the active area which blocks the flow of resin therein. As a contrary, extended elevations are separated by small channels which may serve as outlets of the active area and thus allow for a control of resin flow and resin pressure underneath the active area of the stamp. Possibly, both the reservoir area and the extended elevations are features of the blank area only. The reservoir elevations could also be shaped by blocks, cones or round pillars, triangular pillars, bars, flat or any other shape.

In the imprinting result obtained with a stamp according to the present invention, resin layers with a thickness of at most 5 microns, 2 microns, 1 microns or 0.5 microns may be obtained at positions where the imprinting has been carried out by extended elevations. In general, the height of elevations and the depth of depressions is measured from the second side of the textured area.

The invention also relates to a method for producing an imprinted substrate having a variable depth pattern, in particular by using a stamp according to the present invention, said method comprising the steps of applying (a fraction of) at least one resin upon at least one stamp and/or at least one substrate which is to be imprinted and imprinting at least part of the resin with at least one stamp, preferably wherein at least one stamp comprises at least one textured area at least one barrier adjacent to at least part of the textured area, wherein at least one barrier is configured to create at least one contact surface, such that a substrate provided with an imprinted resin layer is obtained having an imprinted texture which is at least partially adjacent to and/or surrounded by at least one contact surface, wherein the maximum residual layer thickness of at least one contact surface is in particular smaller than the maximum residual layer thickness of the imprinted texture.

The method according to the present invention results in the provision of a product having a texture and a uniform area having a relatively thin thickness which can function as a contact surface. When it is referred to an imprinted substrate also a substrate provided with an imprinted resin layer can be meant, or vice versa. Such contact surface(s) could for example be used for enabling electrical and/or thermal contact and/or for sealing purposes. The method according to the present invention enables that additional processing steps, such as etching, mechanical removal or ablation to form a contact surface can be omitted. In particular, the use of a method which makes use of a stamp comprising at least one barrier according to the present invention contributes to achieving this result. The method in particular enables the production of an imprinted product having a substantially uniform area, or contact surface, having a thickness of 5 μm or less.

The stamp applied in the method according to the present invention can be any of the embodiments described for the stamp according to the present invention. At least part of at least one barrier of the stamp applied in the method has preferably a substantially uniform height which is higher than the highest peak of the at least one textured area. At least one barrier in particular extends over at least the length of at least one side of the textured area. At least one stamp is preferably a flexible stamp.

The resin applied in the method according to the present invention is in particular an imprinting resin. When it is referred to a resin also the term lacquer could be used. Within the context of this invention, the terms “lacquer” and “resin” could be used synonymously. A lacquer or resin according to the present application can be any liquid, or viscous monomeric, oligomeric or polymeric material that can be transferred into a solid material without substantial change of its form and size, thus without shrinking, cracking or expansion. Typically, resins or lacquers according to the present application are materials which can be polymerized using e.g. heat and/or radiation like visible or UV radiation. For this purpose, lacquers or resins may comprise radical initiators. Possible radical initiators are azo compounds such as azobisisobutyronitrile, peroxides such as dibenzoylperoxide or peroxodisulfate, phosphine oxides such as, diphenylphosphine oxide, aromatic ketones such as 1-hydroxy-cyclohexylphenyl-ketone or 2-Hydroxy-2-methylpropiophenone, or a norrish type II initiator such as methylbenzoylformate. Possible cationic and anionic initiators are benzenesulfonic acid esters, alkylsulfonium salts or photo base generators such as Triphenylsulfonium (cationic), Tetrafluoroborate or 2-Nitrobenzyl Cyclohexylcarbamate (anionic). Depending on the initiator the consolidation may be initiated either thermally or by radiation, e.g. UV.

In an embodiment, the resin may be a polymer comprising monomers and/or oligomers such as: epoxides, thiols, polyvinyl resins, acrylates, methacrylates, polyethers, vinylethers, urethane acrylates, polyesters, fluorinated acrylates, fluorinated methacrylates, fluorinated polyethers, siloxanes, siloxane-acrylates or blends thereof. Furthermore, also copolymers of the named monomers as well as oligomers of one or more of the named monomers may be used. In an embodiment, the consolidated resin is impermeable or at least low-permeable for water. In an embodiment, the resin is free or at least essentially free of solvents.

In an embodiment, the resin has the same chemical composition through the whole layer. The resin may be applied to the surface of the product and then be textured by a stamp. The stamp used therefore may be flexible stamp. The flexible stamp may be used in a roll-to-plate process. While being in contact with the stamp, the resin may be consolidated by heat and/or radiation and after consolidation, the stamp may be separated from the resin leaving a textured resin layer on the product. It is imaginable that the stamp is substantially transparent and/or translucent. The stamp is preferably permeable to at least UV light.

The method according to the present invention is preferably directed to a roll-to-plate imprinting method. However, alternatively it is also conceivable that the method is directed to a roll-to-roll imprinting method or a plate-to-plate imprinting method.

The method according to the present invention benefits of the ability to produce a relatively thin residual layer, at least at the area of the obtained contact surfaces. The maximum residual layer thickness of at least one contact surface can for example be at most 5 μm. It is also conceivable that the maximum residual layer thickness of at least one contact surface is below 5 μm, preferably below 3 μm, more preferably between 2 or 1 μm. It is also imaginable that the residual layer thickness of at least one contact surface is in the range of 0.05 to 5 μm, in particular 0.1 to 2 μm, more in particular 0.5 to 1.5 μm.

The textured area of the stamp defines a volume, and the amount of resin applied is preferably larger than the volume defined by the textured area. In this way, an excess amount of resin is applied, in order to ensure sufficient resin to form the desired imprint. The method according to the invention can possibly include the steps of for the formation of a resin layer which is at least in part not thicker than 5 microns comprising the steps of providing a substrate, providing a stamp, the stamp comprising a texture of openings and elevations, the elevations forming a volume, dosing an amount of resin to the stamp which is larger than the volume of the openings but does not cover the elevations of the stamp, bringing the stamp in contact with the substrate, curing the resin while the stamp is in contact with the substrate, and removing the stamp from the substrate. The substrate of the present application is not particularly limited and can be any item that is rigid and comprises a planar surface which might have a necessity for being textured. The substrate can thus be a plain panel of glass, metal, ceramics or resin, any laminate of said materials with each other or with any other material. The substrate may furthermore be a processed or pre-processed device such as a display, a photovoltaic cell, a light screen or any pre-product thereof. The substrate may for example comprise glass, metal, ceramics and/or combination thereof. Dosing of the resin to the stamp may be carried out by any suitable to the person skilled in the art. For dosing, thus a printing technique may be used which doses the resin onto the stamp using a device working according to the same principle as an inkjet printer. In an embodiment, the resin may be pre-cured after dosing in order to increase its viscosity and to thus secure that it stays within the depressions of the stamp until full curing. It is imaginable that the resin is applied in a plurality of fractions, for example in droplets. It is imaginable that the resin is applied in a regular and/or irregular pattern.

The method can include the steps of curing at least part of the resin in particular when the stamp is in contact with the resin and optionally removing the stamp from the substrate, or separating the stamp and the substrate. It is also imaginable that at least part of the resin is pre-cured prior to the curing while the stamp is in contact with the substrate. The viscosity of the resin applied is preferably in the range of 1 mPas till 4000 mPas at 25 C. Preferably, the viscosity of the resin is below 1000 mPas at 25 C and more preferably below 500 mPas at 25 C.

The invention also related to an imprinted product, in particular imprinted by a stamp according to the present invention and/or obtained via applying a method according to the present invention. Said product comprises a resin laying comprising at least one textured area and at least one contact surface, wherein the maximum residual layer thickness of at least one contact surface is smaller than the maximum residual layer thickness of the textured area. The maximum residual layer thickness of at least one contact surface is preferably at most 5 μm. In particular, the maximum residual layer thickness of the resin layer defining at least one contact surface is preferably at most 5 μm. It is also conceivable that the maximum residual layer thickness is below 5 μm, preferably below 3 μm, more preferably between 2 or 1 μm. It is also imaginable that the residual layer thickness is in the range of 0.05 to 5 μm, in particular 0.1 to 2 μm, more in particular 0.5 to 1.5 μm. It is imaginable that the resin layer has a thickness of at most 1 μm, preferably at most 0.5 μm, in particular in at least 15% of the blank area.

The product could further comprise at least one conductive layer, preferably an electrically conductive layer located at least partially underneath the contact surface and/or textured area. It is also imaginable that the product comprises a transparent material and/or a liquid crystal material for example at least partially on top of the resin layer. The transparent layer can be of a transparent electrically conductive material, preferably indium-tin oxide (ITO). The product according to the present invention is not particularly limited and can for example be a product that is rigid and comprises a planar surface. The product might have a necessity for being textured. The product can for example be a plain panel of glass, metal, polymers, ceramics or resin, any laminate of said materials with each other or with any other material. The product may furthermore be a processed or pre-processed device such as a display, a photovoltaic cell, a light screen or any pre-product thereof.

In an embodiment, the product according to the present application may be a substrate that is provided with a resin layer. At least a part of the surface of the resin layer is provided with an optical surface wherein the optical surface is provided with an optical surface texture. At least part of the resin layer can be provided with at least one of: a contact surface or a bonding surface; wherein the contact surface has a thickness optimized for electrical contact and wherein the bonding surface is provided with a surface texture optimized for mechanical bonding, e.g. for bonding of a seal. It is also imaginable that at least one bonding surface is formed by part of the contact surface. The contact surface as defined by the present invention could also be used as bonding surface. In an embodiment, both the contact surface and/or the bonding surface are present on one resin layer. The product may comprise an electrically conductive layer at least partially underneath the resin layer. Said electrically conductive layer may be a closed layer or pattern such as an electric circuit of an electrically conductive material like a metal like copper, silver or aluminum or a non-metallic electrically conductive material such as graphite, graphene, electrically conductive polymers such as polyacetylene or polythiophene. The electrically conductive material may also be a transparent electrically conductive material such as a doped metal oxide such as indium tin oxide (ITO), fluorine-doped tin oxide, aluminum-doped zinc oxide or antimony-doped tin oxide. The electrically conductive layer may be located directly underneath the resin layer or it may be separated from the resin layer by further layers. The electrically conductive layer may comprise of more than one material which different materials may be in part transparent or non-transparent. The different materials may be arranged in a side-by-side manner or on top of each other. In an embodiment, the transparent electrically conductive layer may be bordered or in part or in total be surrounded by a non-transparent electrically conductive layer. In an embodiment, the product may comprise a transparent material at least partially underneath the resin layer. The transparent material may be any transparent material known to the person skilled in the art such as polymers like polycarbonate, polymethyl methacrylate (PMMA), polystyrene, different types of silicate-based glasses like sodium-lime glass, potassium-lime glass, boron-silicate glass, lead glass, quartz glass and also electrically conductive transparent materials such as indium tin oxide (ITO), fluorine-doped tin oxide, aluminum-doped zinc oxide or antimony-doped tin oxide. The transparent material may be a monolithic layer or comprise several layers of different transparent materials such as a layer of ITO on a panel of sodium-lime-glass or PMMA. The layer of transparent material may be located directly underneath the resin layer or it may be separated from the resin layer by further layers. In an embodiment, the layer of transparent material and the electrically conductive layer are the same layer. In an embodiment, the product comprises a layer of liquid crystals on top of the resin layer. In such embodiment, the layer of liquid crystals could for example not be located directly underneath the resin layer but can be separated from the resin layer by a different material which different material may be the transparent and/or the electrically conductive material according to the present application. The product may further comprise a sealing layer which may be arranged adjacent to the electrically conductive layer and/or the transparent layer which sealing layer may be of glass, metal, resin or any other rigid material with low permeability for water and air. In the resin layer on the product, in general an active area as well as a blank area can be distinguished. The active area of the resin layer provides the article with a distinct function such as a desired visual appearance or a certain optical effect. For this purpose, the active area may comprise a texture. Said texture may thus be called a “functional texture” or “optical texture”. However, in some embodiments, the active area may be a smooth surface. The blank area is an area wherein the resin layer does not have the function of the active area. The blank area may by itself be divided in different regions. In the blank area, the function of the resin layer may be a protective one or the one of an adhesion promoter to something that is adhesively bonded to the resin layer such as a top seal which top seal may be located on top of the sealing layer. However, for different reasons, also the blank area may be textured and the texture in the blank area may differ from the texture in the active area. As an example, the texture in the bonding area may be suitable for bonding a top seal thereon. Depending on the material of the top seal, the bonding area may be smoothly textured, slightly sanded or have any other texture known to the person skilled in the art. In an embodiment, the blank area surrounds the active area or is located at least in part at the edges of the active area. In case, the blank area in part surrounds the active area, gaps may be formed in the blank area e.g. for access of cables to the active area or for resin flow control. A part of the blank area may be a lead-in area, which is the area of the first contact of the stamp with the substrate in the imprinting process. The blank area may thus be an area where the resin layer comprises errors or imprinting failures due to start-stop effects of the imprinting process.

The residual layer thickness of the resin layer can be defined as the smallest distance from the upper surface of the resin layer to the surface of the product or substrate, the resin layer is provided on. The resin layer can have a thickness of at most 5 microns in at least 15% of the blank area. Throughout this application, a resin layer of a thickness of at most 5 microns is called a “thin layer” and the regions where it is located are called “thin-layer regions”. In an embodiment, the resin layer may be at most 4.5, 4, 3, 2, 1 or 0.5 microns thick in thin-layer regions.

Note that the thickness of the blank area may be variable both in thin-layer regions and off the thin-layer regions. Note further that the term “thin layer” and “thin-layer regions” only applies to the blank area. The thickness of the resin layer in the active area may be higher than 5 microns, lower than 5 microns or the thickness may vary. In any case, there is no direct relation between the thickness of the resin layer in the active area and in the blank area. In an embodiment, the blank area may consist of thin-layer regions only. In an embodiment, the thin-layer regions are at least 90, 80, 70, 60, 50, 40, 30, 20% or 15% of the blank area. In an embodiment, the thin-layer regions are at most 90, 80, 70, 60, 50, 40, 30 or 20% of the blank area. In an embodiment, the whole blank area is a thin-layer region. All thin-layer regions of the blank area may be connected to each other thus forming one thin-layer region or the thin-layer regions may be separated by regions wherein the resin layer is thicker than 3 microns. The thin-layer regions may form a pattern which is adapted to structures on the product. In an embodiment, the thin-layer regions may in total or in part be located in regions of the resin layer over electrical contacts and/or seals. The thickness of the resin layer may be achieved by imprinting only and not by any substractive and/or reductive manufacturing step such as etching, dissolving, milling, skiving or use of abrasives. A thin-layer region over the electrical contacts will for example allow for forming an electrical connection to electrical contacts covered by the thin resin layer either through the thin resin layer or by punctuation. In an embodiment, punctuation is carried out by local abrasion or by melting and evaporation of resin during a soldering process used for e.g. fixing wires to the contact areas. Throughout this application, the term “texture” means a three-dimensional structure which comprises both openings and elevations which may also be known as “relief” or “relief textures” to the person skilled in the art. In some situations, textures may also be called “patterns”, “relief patterns” or “textured patterns”, however, the term “pattern” may also mean a two-dimensional structure which is produced by selective application of a color such as ink to a surface like in typical printing of colors on paper. In order to have an optical effect, the texture may e.g. comprise small lenses, lenticulars, pyramids, gratins or bars which produce certain optical effects.

The invention alternatively also relates to a block of rigid material suitable as a master for making a textured stamp, the block comprising a first side and a second side, the first side comprising a texture to be replicated, the texture comprising a functional texture in an active area and a passive structure in a blank area, the texture being formed of depressions and elevations, characterized in that the blank area comprises extended depressions which extended depressions are deeper than the deepest depressions in the active area, the depth of the depression measured from the second side of the block. The block, which can synonymously be called “master”, may be of any rigid material such as silicon, quartz, glass, steel, aluminum or any other metal. In an embodiment, the material is both mechanically and chemically durable and thus shows robustness against mechanical forces as well as against chemical stress caused by water, oxygen, heat, organic solvents, acids or bases. Especially the latter simplifies cleaning of the master in case of soiling.

### BRIEF DESCRIPTION OF THE DRAWINGS

The terms Fig., Figs., Figure, and Figures are used interchangeably in the specification to refer to the corresponding figures in the drawings.

The invention will be further elucidated by means of non-limiting exemplary embodiments illustrated in the following figures, in which:

FIGS. 1a-1c show a stamp according to the present invention and the use thereof in a method according to the present invention; and

FIG. 2 shows a possible embodiment of a stamp according to the present invention.

Within these figures, similar reference numbers correspond to similar or equivalent elements or features.

### DESCRIPTION OF THE INVENTION

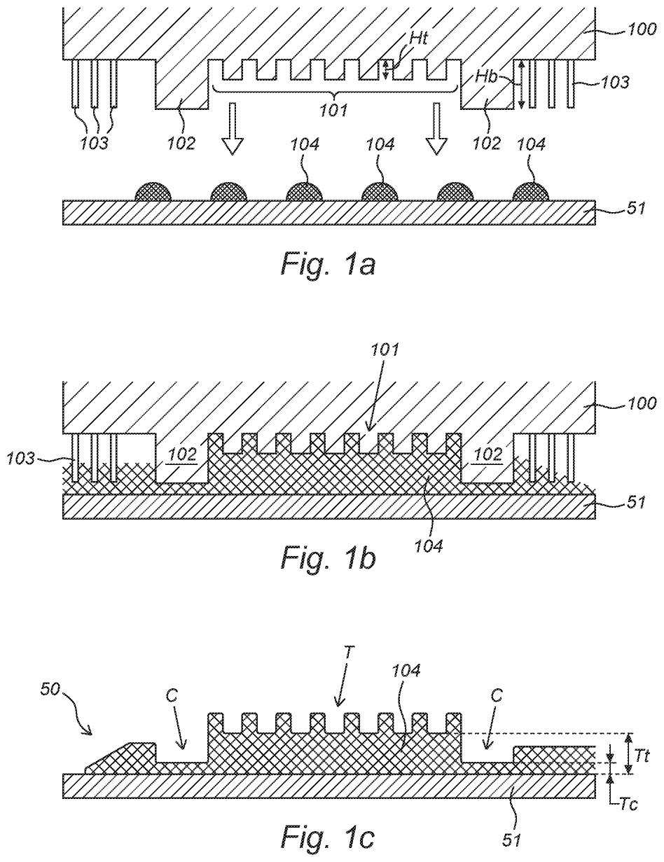

FIGS. 1a-1c show a schematic representation of a stamp 100 according to the present invention and the use thereof in a method according to the present invention in order to produce a product 50 according to the present invention. The figure shows a side viewed perspective. FIG. 1a shows an initial step prior to the imprinting process wherein a substrate 51 is provided and a stamp 100. FIG. 1b shows the imprinting step and FIG. 1c shows the obtained product 50 after imprinting after the stamp 100 being removed from the substrate 51. The stamp 100 is configured for imprinting, in particular nanoimprinting, and comprises a textured area 101 and a barrier 102. The barrier 102 is adjacent to the textured area. The barrier 102 extends over the length of at least one side of the textured area 101, and at least part of the barrier 102 has a substantially uniform height Hb which is higher than the highest peak Ht of the at least one textured area 101. The stamp 100 further comprises a plurality of reservoir elements 103 defining a reservoir volume. In the shown embodiment, the reservoir elements 103 are located at the circumference of the stamp 100 and the height thereof is substantially equal to the height Hb of the barrier 102. The barrier 102 defines a width and a height, and in the shown embodiment the height and width of the barrier are substantially uniform over the entire barrier 102. The barrier 102 further comprises a substantially flat end surface. The end surface could optionally be at least partially structured.

FIG. 1a shows the first step of the method wherein a fraction of a resin 104 is provided upon the substrate 51 which is to be imprinted. The resin 104 could also have been applied to the stamp 100. FIG. 1b shows the imprinting step, wherein imprinting of at least part of the resin 104 upon the substrate 51 with the stamp 100 is performed. Due to the relatively large amount of resin 104 applied and the stamp 100 comprising reservoir elements 103, the excess of resin 104 is directed towards the end surfaces of the substrate 51. The stamp 100 is configured to create a texture T and a contact surface C in the formed resin layer 104. After the stamp 100 is removed, an imprinted substrate 51 or product 50 is obtained, as shown in FIG. 1c. The imprinted substrate 51 has an imprinted texture T which is adjacent to and/or surrounded by a contact surface C and whereof the maximum residual layer thickness Tc of at least one contact surface is smaller than the maximum residual layer thickness Tt of the imprinted textured area T. The maximum residual layer thickness Tc of at least one contact surface is in particular at most 5 μm.

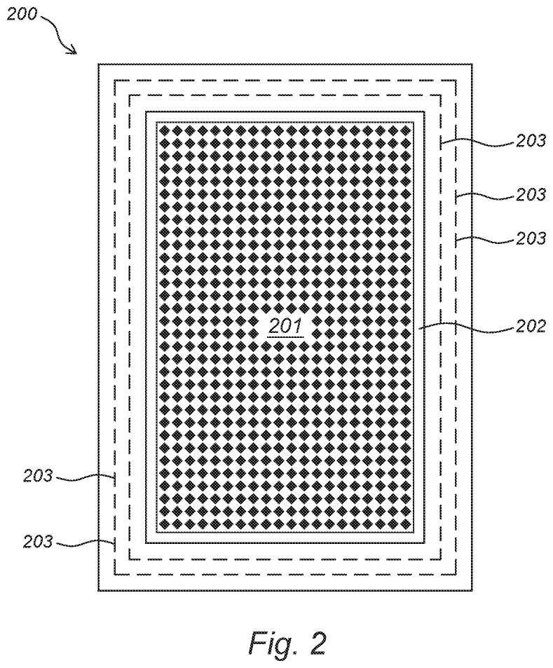

FIG. 2 shows a top view of a possible embodiment of a stamp 200, in particular a flexible stamp 200, according to the present invention. The stamp 200 comprises a textured area 201 and a barrier 202 adjacent to at least part of the at least one textured area 201. The stamp 200 further comprises a plurality of reservoir elements 203 located at the circumference of the stamp 200. The reservoir elements 203 define a reservoir volume. The barrier 202 is a continuous barrier 202 which substantially encloses the textured area 201. The barrier 202 is enclosed between the textured area 201 and the reservoir elements 203. In the shown embodiment, the reservoir elements 203 are positioned at a distance of each other.

It will be clear that the invention is not limited to the exemplary embodiments which are illustrated and described here, but that countless variants are possible within the framework of the attached claims, which will be obvious to the person skilled in the art. In this case, it is conceivable for different inventive concepts and/or technical measures of the above-described variant embodiments to be completely or partly combined without departing from the inventive idea described in the attached claims.

The verb ‘comprise’ and its conjugations as used in this patent document are understood to mean not only ‘comprise’, but to also include the expressions ‘contain’, ‘substantially contain’, ‘formed by’ and conjugations thereof.

1-19. (canceled)

20. A stamp for roll-to-plate imprinting, in particular nanoimprinting, comprising:
at least one textured area; and
at least one barrier adjacent to at least part of the at least one textured area;
wherein the stamp is a substantially flexible stamp and wherein the at least one barrier is a continuous barrier and extends over at least the length of at least one side of the textured area, and wherein at least part of the at least one barrier has a substantially uniform height which is higher than the highest peak of the at least one textured area.

21. The stamp according to claim 20, wherein at least one barrier substantially encloses the at least one textured area.

22. The stamp according to claim 20, wherein at least one barrier defines a width and a height, wherein the height of at least one barrier is substantially uniform and/or wherein the width of the barrier is substantially uniform.

23. The stamp according to claim 20, wherein at least one barrier is a continuous barrier which substantially encloses the at least one textured area.

24. The stamp according to claim 20, wherein at least one barrier comprises a substantially flat end surface.

25. The stamp according to claim 20, comprising at least one reservoir element and preferably a plurality of reservoir elements defining a reservoir volume.

26. The stamp according to claim 25, wherein at least one reservoir element is located at the circumference of the stamp.

27. The stamp according to claim 25, wherein the height of at least one reservoir element is equal to or smaller than the maximum height of at least one barrier.

28. The stamp according to claim 25, wherein at least one reservoir element is positioned on an opposite side of at least one barrier with respect to the textured area.

29. A roll-to-plate imprinting method for producing an imprinted substrate having a variable depth pattern by using a substantially flexible stamp according to claim 20, comprising the steps of:
applying at least one resin upon at least one stamp and/or at least one substrate which is to be imprinted; and
imprinting at least part of the resin with at least one stamp, wherein at least one stamp comprises at least one textured area and at least one barrier adjacent to at least part of the textured area, wherein the at least one barrier is configured to create at least one contact surface, such that a substrate provided with an imprinted resin layer is obtained having an imprinted texture which is at least partially adjacent to and/or surrounded by at least one contact surface, wherein the maximum residual layer thickness of at least one contact surface is smaller than the maximum residual layer thickness of the imprinted texture.

30. A method according to claim 29, wherein at least part of at least one barrier of the stamp has a substantially uniform height which is higher than the highest peak of the at least one textured area.

31. The method according to claim 29, wherein the maximum residual layer thickness of at least one contact surface is at most 5 μm.

32. The method according to claim 29, wherein the textured area of the stamp defines a volume, and wherein the amount of resin applied is larger than the volume defined by the textured area.

33. The method according to claim 29, wherein the resin is applied in a plurality of fractions.

34. The method according to claim 29, comprising the steps of curing at least part of the resin in particular when the stamp is in contact with the resin and optionally separating the stamp and the substrate after curing.

35. A product imprinted by a stamp according to claim 20 and/or a method, said product comprising a resin laying comprising at least one textured area and at least one contact surface, wherein the maximum residual layer thickness of at least one contact surface is smaller than the maximum residual layer thickness of the textured area.

36. The product according to claim 35, wherein the maximum residual layer thickness of at least one contact surface is 5 μm.

37. The product according to claim 35, comprising at least one conductive layer, preferably an electrically conductive layer located at least partially underneath the contact surface and/or textured area.
